(19) United States
(12) Patent Application Publication
(10) Pub. No.: US 2024/0321608 A1
(43) Pub. Date: Sep. 26, 2024

(54) DIAGNOSTIC DEVICE, SEMICONDUCTOR MANUFACTURING EQUIPMENT SYSTEM, SEMICONDUCTOR EQUIPMENT MANUFACTURING SYSTEM, AND DIAGNOSTIC METHOD

(71) Applicant: Hitachi High-Tech Corporation, Minato-ku, Tokyo (JP)

(72) Inventors: Pushe ZHAO, Tokyo (JP); Ryoji ASAKURA, Tokyo (JP); Masahiro SUMIYA, Tokyo (JP)

(21) Appl. No.: 18/026,217

(22) PCT Filed: Mar. 14, 2022
(86) PCT No.: PCT/JP2022/011254

§ 371 Date: Mar. 14, 2023

(51) Int. Cl. H01L 21/67; H01J 37/32; H01L 21/683

(52) U.S. Cl. CPC H01L 21/67248; H01L 21/67253; H01L 21/6833; H01J 37/32935

(57) ABSTRACT

An object of the present disclosure is to provide a technique for detecting an anomaly of the surface state of the film of an electrostatic chuck. In a diagnostic device for diagnosing the state of a semiconductor manufacturing device having a sample stage on which a sample electrostatically adsorbed to a film is mounted, temperature data before and after a change of energy applied to the sample is obtained, and an anomaly of the film is detected on the basis of the obtained temperature data.

### TECHNICAL FIELD

The present disclosure relates to a diagnostic device, a semiconductor manufacturing equipment system, a semiconductor equipment manufacturing system, and a diagnostic method. In particular, the present disclosure relates to a diagnostic device (PHM: Prognostics and Health Management) using time-series signals (sensor waveform data) sequentially obtained from multiple sensors of a plasma processing device which is a semiconductor manufacturing device that processes semiconductor wafers.

### BACKGROUND ART

The surface state of an electrostatic chuck (ESC), which mounts and adsorbs a wafer during plasma processing, gradually deteriorates due to damages of the surface, deposition of deposits, and the like. As a result, an anomaly of the processing speed of the wafer, an anomaly of the adsorption of the wafer, and the like occur. Therefore, techniques for detecting the change of the surface state of the ESC and performing maintenance before such anomalies occur are required. However, real-time monitoring of the surface state of the ESC that is an operating device is difficult due to the lack of associated sensors.

### CITATION LIST

### Patent Literature

PLT 1: Japanese Patent Application Laid-Open NO. 2015-226407

### SUMMARY OF INVENTION

### Technical Problem

An anomaly of the surface state of the ESC is detected by the change of the thermal conductivity of the surface of the ESC. For general devices, a method of detecting the change of thermal conductivity on the basis of the changes of temperature sensor data has been proposed such as a method described in Patent Literature 1. However, in the ESC of an etching device, the value of a temperature sensor is kept constant by a temperature control system, so that this method cannot detect the change of the thermal conductivity of the surface of the ESC.

Accordingly, an object of the present disclosure is to provide a technique for detecting an anomaly of the surface state of the film of an electrostatic chuck.

### Solution to Problem

A brief outline of a representative one of the present disclosure is as follows.

According to one embodiment, in a diagnostic device for diagnosing the state of semiconductor manufacturing device having a sample stage on which a sample electrostatically adsorbed to a film is mounted, temperature data before and after a change of energy applied to the sample is obtained, and an anomaly of the film is detected on the basis of the obtained temperature data.

In addition, the diagnostic device of the present disclosure, which can predict an anomaly, changes energy applied to a wafer using a plasma control division, obtains temperature change data before and after the change of the energy from a temperature sensor in a data collection division, calculates the change amount or the change speed of the temperature change data as a feature amount in a feature amount calculation division, and determines that the surface state of the electrostatic chuck is anomalous if it is judged that the feature amount exceeds a threshold in an anomaly detection division.

### Advantageous Effects of Invention

It becomes possible to improve the accuracy of detecting an anomaly of the surface state of the electrostatic chuck.

### BRIEF DESCRIPTION OF DRAWINGS

FIG. 1 is a diagram showing an example of a configuration of a failure diagnostic device according to Example 1.

FIG. 2 is a diagram showing an example of an electrode configuration of an etching device shown in FIG. 1.

FIGS. 3A-3C are diagrams showing examples of sensor data according to Example 1.

FIG. 4 is a diagram showing an example of a processing flow of feature amount calculation and anomaly determination according to Example 1.

FIG. 5 is a diagram showing calculation examples of feature amounts F1, F2, and F3.

FIG. 6 is a diagram showing a calculation example of the feature amount F4.

FIGS. 7A-7E are diagrams showing an example of anomaly determination according to Example 1.

FIGS. 8A-8D are diagrams showing an example of a wafer chucking operation according to Example 2.

FIG. 9 is a diagram showing an example of a diagnostic result display according to Example 1.

### DESCRIPTION OF EMBODIMENTS

Embodiments of the present invention are diagnostic devices each of which is a plasma processing device. As an example of the embodiments, a diagnostic device may be a general personal computer that includes a processor and a memory and implements software for executing various processes according to programs, or may be a device that implements dedicated hardware instead of a general computer.

Alternatively, the diagnostic device may be a device implementing a combination of software and hardware by incorporating dedicated hardware into a computer. The diagnostic device may be externally connected to a semiconductor manufacturing equipment system, or externally connected as a module shared with other data processing. Hereinafter, the embodiments will be explained with reference to the accompanying drawings.

### Example 1

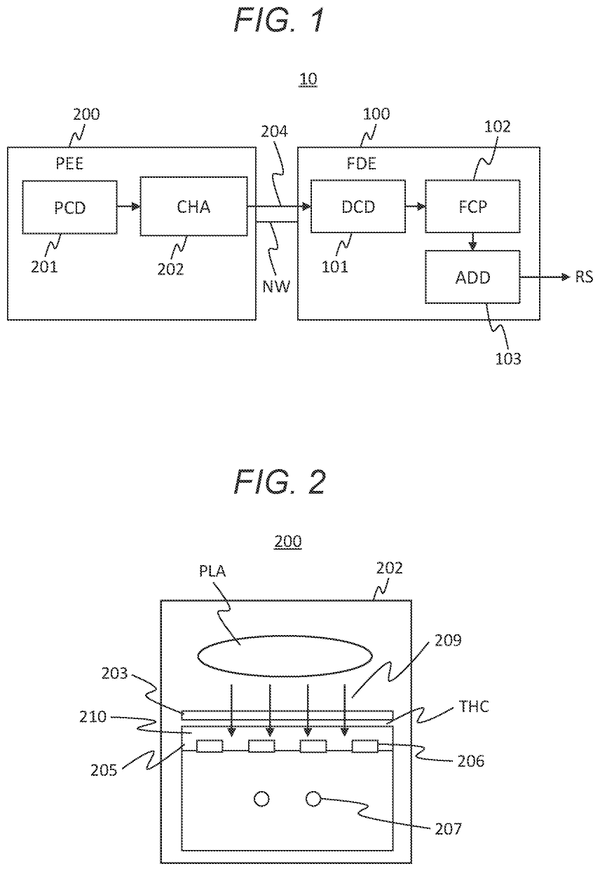

A semiconductor manufacturing equipment system 10 shown in FIG. 1 includes a fault diagnostic device (FDE, sometimes simply referred to as a diagnostic device) 100 and an etching device (PEE) 200. The failure diagnostic device 100 and the etching device 200 are connected to each other via a network line NW. In this example, the etching device 200 is a plasma processing device that is a semiconductor manufacturing device.

The failure diagnostic device (FDE) 100 includes: a data collection division (DCD) 101; a feature amount calculation division (FCP) 102; an anomaly detection division (ADD) 103, and the failure diagnostic device (FDE) 100 is connected to the etching device 200 via the network line NW. The etching device 200 includes a plasma control division (PCD) 201 and a chamber (CHA) 202 both of which are associated with the present invention. The failure diagnostic device 100 receives time-series data (hereinafter referred to as sensor data) 204 measured by a sensor during a processing process from the etching device 200 via the network line NW, analyzes the received sensor data 204, and outputs an analysis result RS.

The plasma control division 201 controls energy applied to a wafer 203, which is a sample, in the chamber 202. In the chamber 202, the wafer 203 is processed under set process conditions, and sensor data 204 obtained in this process is transmitted to the data collection division 101 in real time. The data collection division 101 extracts energy data and temperature sensor data from the received sensor data 204, and transmits the extracted data to the feature amount calculation division 102. The feature amount calculation division 102 obtains temperature change data before and after the change of the energy from the sensor data 204, and calculates the change amount or the change speed of the temperature change data as a feature amount. The anomaly detection division 103 analyzes the change of the calculated feature amount over time, and outputs an analysis result RS whether there is an anomaly or not.

FIG. 2 shows an example of the configuration of the chamber 202. In the chamber 202, a sample stage that includes an electrostatic chuck (ESC) 205, which mounts a wafer 203 thereon and electrostatically adsorbs the wafer 203 during plasma processing, is installed. On the sample stage, the wafer 203 electrostatically adsorbed to a film 210 that forms the ESC 205 is mounted. While the wafer 203 is processed, the temperature of the ESC 205 is controlled according to process setting conditions, the wafer 203 is moved above the ESC 205, and plasma PLA is generated in a space above the wafer 203. The purpose of the present invention is to detect an anomaly of the surface state of the film 210 of the ESC 205 by monitoring the change of a thermal conductivity THC between the wafer 203 and the ESC 205, since the surface state of the film 210 of the ESC 205 is related to the thermal conductivity THC.

The temperature of the ESC 205 is controlled by a feedback temperature control system using a plurality of heaters 206 and a plurality of temperature sensors 207. The feedback temperature control system controls heater powers to decrease when the temperatures of the temperature sensors 207 are higher than the temperature of a setting condition, and controls the heater powers to increase when the temperatures of the temperature sensors 207 are lower than the temperature of the setting condition. Therefore, the sensor values (detected temperature values) of the temperature sensors 207 are almost constant during the process. When there is the change of a heat source or the like, the sensor values of the temperature sensors 207 change temporarily, but since the temperature control by the feedback temperature control system is operated, the temperatures of the temperature sensors 207 return to the temperature of the setting condition.

Temperature change data is obtained from the phenomenon described above, and the change of the thermal conductivity THC can be estimated using the temperature change data. For example, when the power of the plasma PLA is changed, the amount of energy (inputted plasma heat) 209 inputted from the plasma PLA to the wafer 203 changes, and the sensor values of the temperature sensors 207 temporarily deviate from the value of the setting condition and afterward return to the value of the setting condition. The change speed of the temperature change is calculated from temperature change data during this process, and if the change speed is faster than usual, it can be seen that the thermal conductivity THC has increased.

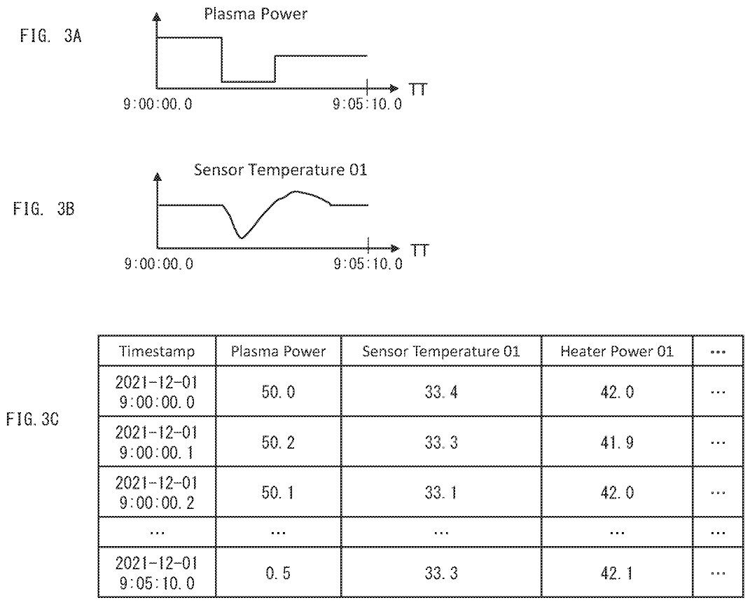

FIG. 3A-3C show examples of the sensor data. FIG. 3A is an example of the sensor data showing the time change of the plasma power (Plasma Power) of the plasma PLA, where the vertical axis represents the plasma power, and the horizontal axis represents the time (TT). FIG. 3B is an example of the sensor data showing the change over time of a temperature sensor value (Sensor Temperature 01) of a temperature sensor 207, where the vertical axis represents the temperature sensor value, and the horizontal axis represents the time (TT). FIG. 3C is a table showing an example of sensor data collected at intervals of 0.1 seconds. Time stamps (Timestamp) are printed at intervals of 0.1 seconds, and the sensor data that is, in this example, the power of the plasma PLA (Plasma Power), the temperature sensor value (Sensor Temperature 01), the power of a heater 206 (Heater Power 01), and the like are exemplified.

As shown in FIG. 3A, the plasma power (Plasma Power) of the plasma PLA is set to decrease once and then increase. As shown in FIG. 3B, the temperature sensor value (Sensor Temperature 01) decreases and then increases in response to the decrease of the plasma power of the plasma PLA. The temperature sensor value of the temperature sensor 207 increases and then decreases in response to the increase of the plasma PLA. The sensor data is collected at intervals of 0.1 seconds and is stored as shown in table of FIG. 3C or transmitted.

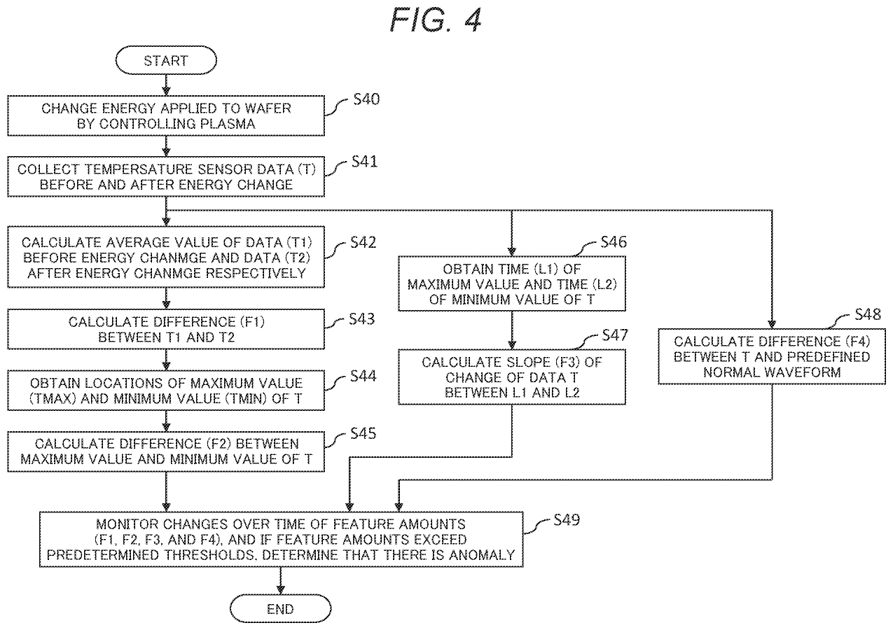

A processing flow of feature amount calculation will be described with reference to FIG. 4. FIG. 4 is a diagram showing an example of a processing flow of feature amount calculation and anomaly determination according to the example 1. The processing flow shown in FIG. 4 is a processing flow executed by an application in a semiconductor equipment manufacturing system having a platform on which the application for diagnosing the state of the semiconductor manufacturing device is installed.

### Step S40:

First, in the semiconductor manufacturing device 200 having the sample stage on which a sample (wafer) 203 electrostatically adsorbed to the film 210 of the ESC 205 is mounted, energy applied to the wafer 203 is changed by controlling plasma power. In this case, although the portion of plasma power change defined in the original process processing conditions can be used, a processing condition dedicated to failure diagnosis may be added to the original process processing conditions.

### Step S41:

Then, sensor data (T) before and after the energy change executed in Step S40 (before and after the energy is changed) is collected. For example, sensor data (T) is collected for a time range of 25 seconds from 5 seconds before the energy change to 20 seconds after the energy change. That is, in the diagnostic device 100 for diagnosing the state of the semiconductor manufacturing device 200 having the sample stage on which the sample 203 electrostatically adsorbed to the film 210 of the ESC 205 is mounted, the sensor data (hereinafter also referred to as the temperature data) T before and after the change of the energy applied to the sample 203 is obtained. And then anomaly of the film 210 of the ESC 205 is detected by the diagnostic device 100 on the basis of the obtained temperature data T.

### Step S42:

From here on, the data T is used to calculate the feature amount F1. Data T1 before the energy change is extracted. For example, the first 10 pieces of data T are taken as data (T1). Data T2 after the energy change is extracted. For example, the last 10 pieces of data T are taken as data (T2). Then, average values (MEAN(T1) and MEAN(T2)) are calculated using the data (T1) before the energy change and the data (T2) after the energy change respectively.

### Step S43

Then, the feature amount F1 is calculated by Expression 1.

$$F 1 = MEAN ( T 1 ) - MEAN ( T 2 ) \qquad Expression ( 1 )$$

A difference (the feature amount F1) between the average value of T1 and the average value of T2 is calculated by Expression (1). That is, the difference between the average value of the temperature data (T1) before the energy change and the average value of the temperature data (T2) after the energy change is obtained as the feature amount F1.

### Step S44:

Next, the maximum value (TMAX) and the minimum value (TMIN) of the data T are obtained.

### Step S45:

Then, the feature amount F2 is calculated by Expression (2).

$$F 2 = TMAX - TMIN \qquad Expression ( 2 )$$

A difference (the feature amount F2) between the maximum value and the minimum value of the temperature data T is calculated by Expression 2. That is, the difference between the maximum value and the minimum value of the temperature data T is obtained as the feature amount F2.

### Step S46:

Next, the time (L1) of the maximum value (TMAX) of the data T and the time (L2) of the minimum value (TMIN) of the data T are obtained.

### Step S47:

The slope of the data T between the time L1 and the time L2 with respect to time is calculated as the feature amount F3. That is, using data between the maximum value (TMAX) of the temperature data T and the minimum value (TMIN) of the temperature data T, the slope with respect to a time width (L1 to L2) is obtained as the feature amount F3.

### Step S48:

Normal waveform data for the data T is prepared before this process. This normal waveform data is the past data T extracted under the same calculation condition from the sensor data of the past normal processing process. The feature amount F4 is calculated by Expression (3).

$$F 4 = MEAN ( a difference between the data T and the normal waveform data at each time ) \qquad Expression ( 3 )$$

The difference between the temperature data T and the predefined normal waveform data (feature amount F4) is calculated by Expression 3. That is, the difference between the predefined normal waveform data of temperature data in the normal state and the waveform data of the temperature data T is obtained as the feature amount F4.

### Step S49:

With the above calculations, the calculations of the feature quantities F1, F2, F3, and F4 are completed. The changes over time of the feature amounts (F1, F2, F3, and F4) are monitored, and if the changes over time of the feature amounts exceed predetermined thresholds, it is determined that there is an anomaly. At the times of the above calculations, a general statistical processing method may be added to the feature amount calculation method for purposes of noise reduction and the like. Furthermore, the number of feature amounts may be increased when a plurality of local maximum and local minimum values can be obtained instead of the maximum and minimum values depending on the pattern of plasma power change.

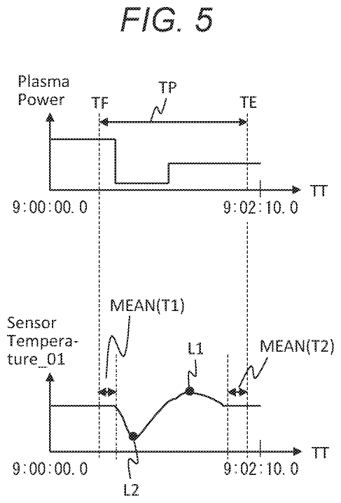

FIG. 5 shows examples of the feature amounts F1, F2, and F3. The plasma power changes twice, and the data T is data during a time interval TP from the time TF before 5 seconds of the first energy change to the TE after 20 seconds of the last energy change. T1 average (MEAN(T1)) is calculated using the first 10 pieces of data T, and T2 average (MEAN(T2)) is calculated using the last 10 pieces of data, and the feature amount F1 can be calculated. In addition, using the maximum value L1 and the minimum value L2 of the data T and the data T between the maximum value L1 and the minimum value L2, the feature amount F2 and the feature amount F3 can be calculated respectively.

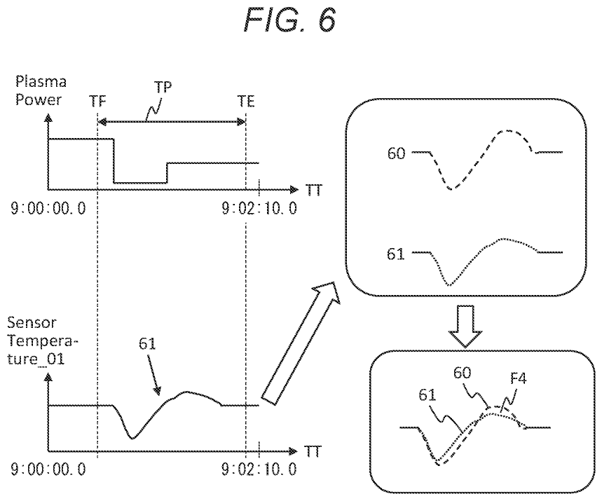

FIG. 6 shows an example of the feature amount F4. Data T(61) is obtained in the same way as in the example of FIG. 5. Then, the feature amount F4 that is a difference between a normal waveform data 60 and a data T (61) can be calculated.

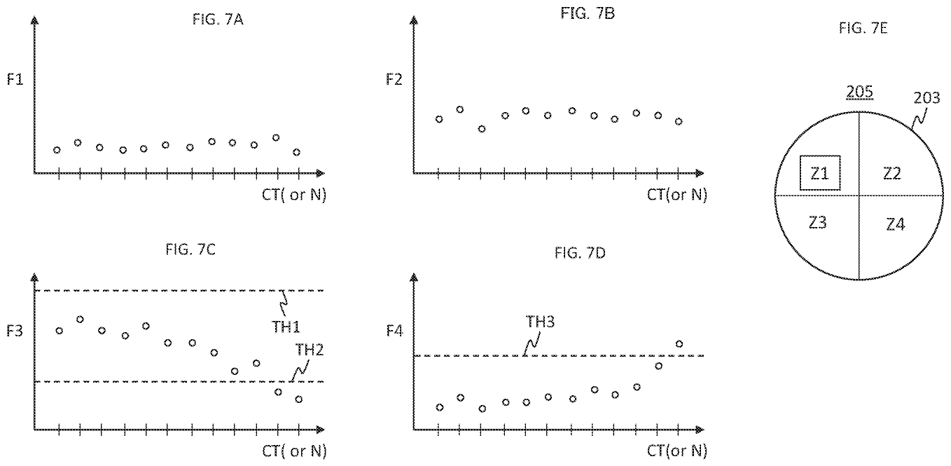

FIG. 7A-7E are diagrams showing an example of anomaly determination. FIG. 7A is an example of the result of monitoring the change over time of the feature amount F1, where the vertical axis represents the value of the feature amount F1, and the horizontal axis represents a cumulative etching time CT (abbreviated as CT) or the number of processed wafers N (abbreviated as N). FIG. 7B is an example of the result of monitoring the change over time of the feature amount F2. The vertical axis represents the value of the feature amount F2, and the horizontal axis indicates the cumulative etching time CT (or the number of the processed wafers N). FIG. 7C is an example of the result of monitoring the change over time of the feature amount F3, where the vertical axis represents the value of the feature amount F3, and the horizontal axis represents the cumulative etching time CT (or the number of processed wafers N). FIG. 7D is an example of the result of monitoring the change over time of the feature amount F4, where the vertical axis represents the value of the feature amount F4, and the horizontal axis represents the cumulative etching time CT (or the number of processed wafers N).

As shown in FIG. 7A-7E, the anomaly determination is performed by analyzing the time series of the feature amounts. For example, there are an upper threshold TH1 and a lower threshold TH2 for the feature amount F3, and if the value of the feature amount F3 exceeds the thresholds TH1 or falls below the threshold TH2, it is determined that the feature amount F3 is anomalous. That is, when the feature amount F3 exceeds a range between the thresholds TH1 and TH2, it is determined that the feature amount F3 is anomalous, (that is, when the feature amount F3 deviates from the range between TH1 and TH2 (F3>TH1 or TH2>F3), it is determined that the feature amount F3 is anomalous). There is one threshold TH3 for the feature amount F4, and when the feature amount F4 exceeds the threshold TH3, the feature amount F4 is determined to be anomalous (that is, when F4>TH3, the feature amount F4 is determined to be anomalous). Overall, when any one of the feature amounts F1, F2, F3, and F4 becomes anomalous, it is determined that an anomaly has occurred in the device. Alternatively, depending on relationships among the feature amounts and failures, it may be determined that the etching device 200 is anomalous when two or more feature amounts are anomalous.

In addition, there is a type of ESC 205 having multiple zones. FIG. 7E shows a type of ESC 205 having four zones (a first zone Z1, a second zone Z2, a third zone Z3, and a fourth zone Z4). The processing flow of the calculation of feature amounts (F1 to F4) and the anomaly determination in FIG. 4 shows, for example, the processing flow of the calculation of feature amounts (F1 to F4) and anomaly determination in the first zone Z1 of the ESC 205. Using the processing flow of feature amounts (F1 to F4) calculation and the anomaly determination shown in FIG. 4 for each of the zones Z1, Z2, Z3, and Z4, feature amounts (F1 to F4) can be calculated, and an anomaly determination can be executed for each of the zones Z1, Z2, Z3, and Z4.

That is, a diagnostic method for diagnosing the state of the semiconductor manufacturing device 200 having the sample stage on which a sample 203 electrostatically adsorbed to the film 210 is mounted is configured to includes a step of obtaining temperature data before and after the change of energy applied to the sample 203 and a step of detecting an anomaly of the film 210 on the basis of the obtained temperature data.

Furthermore, the semiconductor manufacturing equipment system 10 shown in FIG. 1 can be rephrased as a semiconductor equipment manufacturing system. Here, a semiconductor equipment manufacturing system is connected to the semiconductor manufacturing device 200 via a network NW and includes a platform on which an application for diagnosing the state of the semiconductor manufacturing device 200 having a sample stage is implemented, where a sample 203 electrostatically attracted to a film 210 is mounted on the sample stage. Then, the semiconductor device manufacturing system is configured in such a way that the application executes the step of obtaining temperature data before and after energy applied to the sample 203 changes and the step of detecting an anomaly of the film 210 on the basis of the obtained temperature data.

A list of the feature amounts, calculation results, anomaly diagnosis results, and the like can be displayed on a GUI (Graphic User Interface). For example, the diagnostic device 100 includes a display screen for displaying a list of the feature amounts, calculation results, anomaly diagnosis results, and the like using a GUI (Graphic User Interface). Alternatively, in the case where an analysis result RS outputted by the diagnostic device 100 is transmitted to a server via a network line, a display screen for displaying a list of the feature amounts, calculation results, anomaly diagnosis results, and the like using a GUI (Graphic User Interface) may be provided to the server.

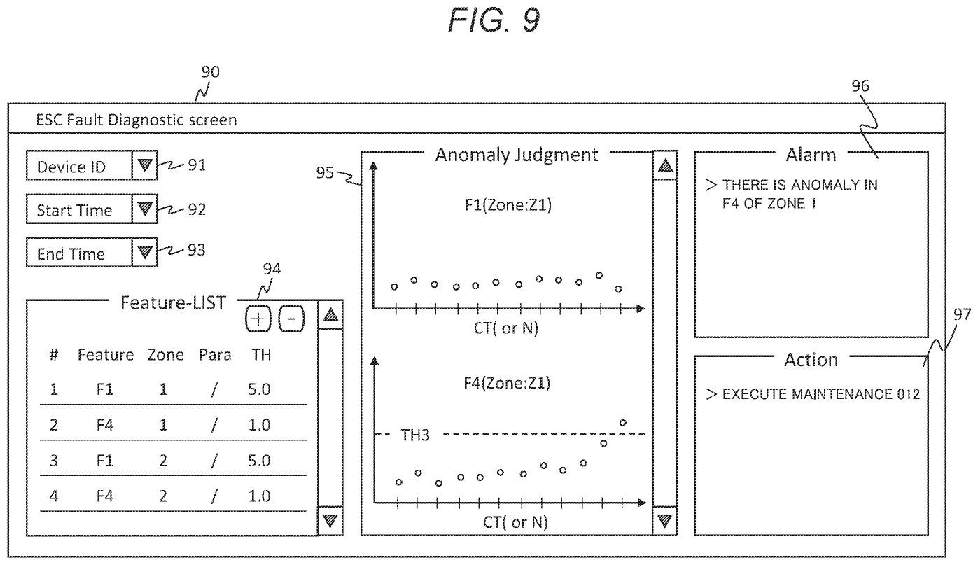

FIG. 9 shows an example of a GUI screen. An example of an ESC fault diagnostic screen (ESC Fault Diagnostic screen) is depicted on the GUI screen 90 of FIG. 9. On the GUI screen 90, the device data (temperature data T) of a semiconductor manufacturing device 200 to be diagnosed with a device ID (Device ID) 91, a start time (Start Time) 92, and an end time (End Time) 93 of the semiconductor manufacturing device 200 can be selected. In a feature amount list (Feature-LIST) 94, a feature amount used for diagnosis (Feature: F1, F2, F3, or F4), a zone (Zone: 1=Z1, 2=Z2, 3=Z3, or 4=Z4), a parameter value (Para) and a threshold (TH) can be set. In the area 95 of anomaly judgment (Anomaly Judgment), the temporal change of each calculated feature amount (F1 to F4) is displayed. When it is determined that there is an anomaly, a feature amount (F4 in this example) that has the anomaly is presented in the alarm (Alarm) area 96. Work such as maintenance and process condition adjustment is presented on the action (Action) area 97 as countermeasures against the anomaly. In other words, the feature amounts (F1, F2, F3, F4) that are the change amounts of the temperature data or the change speeds of the temperature data, the changes of the feature amounts (F1, F2, F3, F4) over time, or a result of the presence or absence of an anomaly of the film 210 are displayed on the GUI screen 90, and when the film 210 is anomalous, an action to be taken when the film 210 is anomalous is presented on the GUI screen 90.

According to Example 1, it is possible to provide a technique for detecting an anomaly in the surface state of the film 210 of the electrostatic chuck 205. This improves the accuracy of detecting an anomaly in the surface state of the film 210 of the electrostatic chuck 205.

### Example 2

In Example 2, processing using wafer chucking 80 (in this case a wafer 203 is mounted on the ESC 205) will be explained instead of using inputted plasma heat. In Example 2, portions about which descriptions are not made are the same as the relevant portions in Example 1. In other words, redundant explanations about the portions that are the same as Example 1 will be omitted.

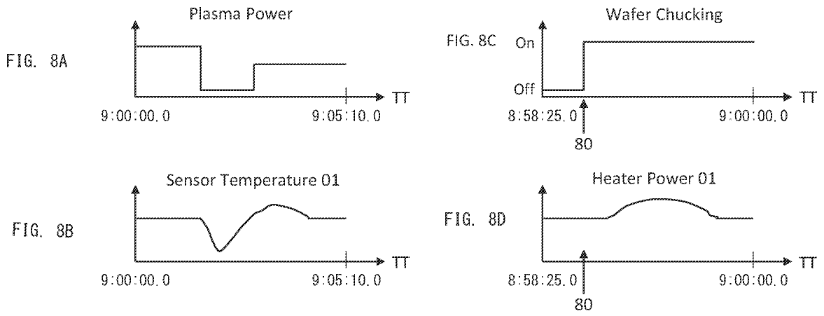

FIG. 8A and FIG. 8B show the states of Example 1 (same as FIG. 3A and FIG. 3B), and FIG. 8C and FIG. 8D show examples using the wafer chucking 80. FIG. 8C shows a change between the on state (On) and the off state (Off) of the wafer chucking 80, the vertical axis represents the on state (On) and the off state (Off) of the wafer chucking 80, and the horizontal axis represents the time TT. FIG. 8D shows the state of the heater power value (data P), which is the amount of power consumed by the heater 206, the vertical axis represents the state of the heater power value (data P), and the horizontal axis represents the time TT.

Instead of the temperature sensor value (data T) used for the feature amount calculation in Example 1, the heater power value (data P), which is the amount of power consumed by the heater, is used in Example 2.

That is, before the wafer chucking 80, the temperature sensor value and the heater power value are kept constant by the temperature control. Since the temperature of the wafer 203 is lower than the temperature of the ESC 205 during the operation of the wafer chucking 80, the temperature of the ESC 205 becomes low. The temperature control system detects the temperature change of the ESC 205 and increases the heater power of the heater 206. When the temperature of the wafer 203 becomes the same as the temperature of the ESC 205, the heater power value of the heater 206 gradually returns to its original value.

Using the data P obtained in the above process, feature quantities can be calculated in the same way as in Example 1, and anomaly determination can be made.

In other words, in Example 2, the power consumption of the heater 206 is obtained instead of the temperature data before and after the change of the energy applied to the sample 203, and an anomaly of the film 210 is detected on the basis of the obtained change data of the power consumption of the heater 206.

A modification example may be configured in such a way that temperature data of the ESC 205 before and after the sample 203 is electrostatically adsorbed is obtained instead of the temperature data before and after the change of the energy inputted to the sample 203 and an anomaly of the film 210 is detected on the basis of the obtained temperature data of the ESC 205 before and after the sample 203 is electrostatically adsorbed.

In Example 2 and the modification example, the same effect as in Example 1 can be obtained as well.

Although the invention achieved by the present inventors has been specifically described so far on the basis of the examples, it goes without saying that the invention is not limited to the above-described embodiment and examples, and the invention can be variously modified.

### REFERENCE SIGNS LIST

10 . . . semiconductor manufacturing equipment system,
100 . . . failure diagnostic device (diagnostic device),
101 . . . data collection division,
102 . . . feature amount calculation division,
103 . . . anomaly detection division,
200 . . . etching device (semiconductor manufacturing device),
201 . . . plasma control division,
202 . . . chamber,
203 . . . sample (wafer),
205 . . . electrostatic chuck (ESC),
206 . . . heater,
207 . . . temperature sensor

1. A diagnostic device for diagnosing the state of a semiconductor manufacturing device having a sample stage on which a sample electrostatically adsorbed to a film is mounted,
wherein temperature data before and after a change of energy applied to the sample is obtained, and
an anomaly of the film is detected on the basis of the obtained temperature data.

2. The diagnostic device according to claim 1,
wherein a difference between the average value of a temperature data before the change of the energy and the average value of the temperature data after a change of the energy is obtained as a feature amount.

3. The diagnostic device according to claim 1,
wherein a difference between the maximum value of the temperature data and the minimum value of the temperature data is obtained as a feature amount.

4. The diagnostic device according to claim 1,
wherein a slope with respect to time is obtained as a feature amount using data between the maximum value of the temperature data and the minimum value of the temperature data.

5. The diagnostic device according to claim 1,
wherein a difference between predefined normal temperature data and the temperature data is obtained as a feature amount.

6. The diagnostic device according to claim 1,
wherein a feature amount that is a change amount of the temperature data or a change speed of the temperature data, a change of the feature amount over time or a result of the presence or absence of an anomaly of the film are displayed on a GUI screen, and if the film is anomalous, an action is proposed as well.

7. The diagnostic device according to claim 1,
wherein temperature data before and after the sample is electrostatically adsorbed is obtained instead of the temperature data before and after the change of the energy applied to the sample, and
an anomaly of the film is detected on the basis of the obtained temperature data.

8. The diagnostic device according to claim 1,
wherein the power consumption amount of a heater is obtained instead of the temperature data before and after the change of the energy applied to the sample, and
an anomaly of the film is detected on the basis of the change data of the obtained power consumption amount of the heater.

9. A semiconductor manufacturing equipment system connected to a semiconductor manufacturing device via a network, the semiconductor manufacturing equipment system comprising the diagnostic device according to claim 1.

10. The semiconductor manufacturing equipment system according to claim 9,
wherein the diagnostic device is a personal computer.

11. A semiconductor equipment manufacturing system to which a semiconductor manufacturing device having a sample stage on which a sample electrostatically adsorbed to a film is mounted is connected via a network, the semiconductor equipment manufacturing system comprising a platform in which an application for diagnosing the state of the semiconductor manufacturing device is installed,
wherein a step of obtaining temperature data before and after the change of energy applied to the sample, and
a step of detecting an anomaly of the film on the basis of the obtained temperature data are performed by the application.

12. A diagnostic method for diagnosing the state of a semiconductor manufacturing device having a sample stage on which a sample electrostatically adsorbed to a film is mounted, the diagnostic method comprising the steps of:
obtaining temperature data before and after a change of energy applied to the sample; and
detecting an anomaly of the film on the basis of the obtained temperature data.
